(19) United States
(12) Patent Application Publication
(10) Pub. No.: US 2026/0130022 A1
(43) Pub. Date: May 7, 2026

(54) Interposer and Method of Manufacturing Display Device Using the Same

(71) Applicant: LG Display Co., Ltd., Seoul (KR)

(72) Inventor: DongSeok Lee, Bucheon-si (KR)

(21) Appl. No.: 19/319,024

(22) Filed: Sep. 4, 2025

(30) Foreign Application Priority Data
Nov. 4, 2024 (KR) 10-2024-0154271

(51) Int. Cl. H10H 29/03; H10H 29/39

(52) U.S. Cl. CPC H10H 29/03; H10H 29/39

(57) ABSTRACT

The present application discloses an interposer and a method of manufacturing a display device using the same. An interposer includes a base portion and a plurality of protrusions that are spaced apart from each other on the base portion, and each of the plurality of protrusions includes a side wall extending upward from the base portion to define an accommodation unit. Therefore, it is possible to reduce a misalignment caused by a temperature deviation.

### CROSS-REFERENCE TO RELATED APPLICATION

This application claims the priority of Republic of Korea Patent Application No. 10-2024-0154271 filed on Nov. 4, 2024, which is hereby incorporated by reference in its entirety.

### BACKGROUND

### Field

The present disclosure relates to an interposer and a method of manufacturing a display device using the same, and more particularly, to an interposer which improves a transfer precision of a light emitting diode and a method of manufacturing a display device using the same.

### Description of the Related Art

As display devices which are used for a monitor of a computer, a television, or a cellular phone, there are an organic light emitting display device (OLED) which is a self-emitting device and a liquid crystal display device (LCD) which requires a separate light source. An applicable range of the display device is diversified to personal digital assistants as well as monitors of computers and televisions and a display device with a large display area and a reduced volume and weight is being studied.

Further, recently, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance may be displayed.

### SUMMARY

An object to be achieved by the present disclosure is to provide an interposer in which a misalignment of a light emitting diode is minimized and a method of manufacturing a display device using the inteposer.

Another object to be achieved by the present disclosure is to provide an interposer which reduces recognition of a mura defect generated as a plurality of light emitting diodes are transferred to the display device according to the alignment as it is grown on a growth substrate and a method of manufacturing a display device using the same.

Still another object to be achieved by the present disclosure is to provide an interposer whose number of transfer processes is reduced by using a contactless transfer method and a method of manufacturing a display device using the same.

Still another object to be achieved by the present disclosure is to provide an interposer which relieves an impact applied to a light emitting diode in a contactless transfer method and a method of manufacturing a display device using the same.

Still another object to be achieved by the present disclosure is to provide an interposer in which a plurality of bumps to which a plurality of light emitting diodes are attached is formed to be spaced apart from each other to increase a pressure applied to the plurality of bumps and a non-transferring problem of the light emitting diode is reduced and a method of manufacturing a display device using the same.

Objects of the present disclosure are not limited to the above-mentioned objects, and other objects, which are not mentioned above, can be clearly understood by those skilled in the art from the following descriptions.

In one embodiment, an interposer that transfers light emitting diodes onto a target substrate comprises: a base portion; and a plurality of protrusions on an upper surface of the base portion and spaced apart from each other on the upper surface of the base portion, each of the plurality of protrusions including a side wall extending in a direction away from the upper surface of the base portion, wherein the side wall defines an accommodation unit that is configured to contain a light emitting diode.

In one embodiment, a method of manufacturing a display device, comprises: placing a temporary substrate above an interposer that includes a plurality of insulating members, wherein a plurality of light emitting diodes including a first electrode and a second electrode are disposed on the temporary substrate; transferring the plurality of light emitting diodes that are on the temporary substrate to the plurality of insulating members of the interposer, wherein a side surface and one surface of the first electrode of each of the plurality of light emitting diodes is surrounded by a corresponding insulating member from the plurality of insulating members after the plurality of light emitting diodes are transferred to the plurality of insulating members; and transferring the plurality of light emitting diodes that are on the plurality of insulating members and the plurality of insulating members to a target substrate by attaching the interposer to the target substrate.

In one embodiment, a display device comprises: a substrate; a thin film transistor on the substrate; a micro light emitting diode that is electrically connected to the thin film transistor, the micro light emitting diode including a first electrode; an insulating member in contact with and surrounding side surfaces and a portion of an upper surface of the micro light emitting diode such that at least a portion of the first electrode is exposed, the insulating member diffusing light emitted by the micro light emitting diode; a planarization layer surrounding a side surface of the insulating member; a common electrode on the planarization layer, the common electrode connected to the first electrode that is exposed by the insulating member; and a voltage line on the substrate, the voltage line connected to the common electrode.

Other detailed matters of the exemplary embodiments are included in the detailed description and the drawings.

According to the present disclosure, as the interposer, a material having a low coefficient of thermal expansion is applied to reduce a misalignment caused by a temperature deviation.

According to the present disclosure, light emitting diodes which are formed on a plurality of growth substrates are uniformly disposed on the interposer to suppress a mura defect according to the growth substrate from being recognized from the display device.

According to the present disclosure, a contactless transfer method is used to use a large size interposer and reduce the number of transfer processes, thereby implementing process optimization.

According to the present disclosure, when an insulating member of the interposer accommodates a light emitting diode which is transferred by a contactless manner, breakage of the light emitting diode may be suppressed.

According to the present disclosure, in the interposer, a plurality of bumps are spaced apart from each other to improve a transfer success rate of a light emitting diode.

The effects according to the present disclosure are not limited to the contents exemplified above, and more various effects are included in the present specification.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a plan view of an interposer according to an exemplary embodiment of the present disclosure;

FIG. 2 is a cross-sectional view of an interposer according to an exemplary embodiment of the present disclosure;

FIGS. 3A to 3H are schematic diagrams for explaining a method for manufacturing a display device using an interposer according to an exemplary embodiment of the present disclosure;

FIG. 4 is a cross-sectional view of an interposer according to another exemplary embodiment of the present disclosure;

FIG. 5 is a cross-sectional view of an interposer according to still another exemplary embodiment of the present disclosure;

FIGS. 6A and 6B are cross-sectional views of an interposer according to still another exemplary embodiment of the present disclosure;

FIG. 7 is a cross-sectional view of an interposer according to still another exemplary embodiment of the present disclosure;

FIG. 8 is a cross-sectional view of an interposer according to still another exemplary embodiment of the present disclosure;

FIG. 9 is a cross-sectional view of an interposer according to still another exemplary embodiment of the present disclosure;

FIG. 10 is a schematic diagram of a display device according to an exemplary embodiment of the present disclosure; and

FIG. 11 is a cross-sectional view of a display device according to an exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, the layer or the element may be disposed directly on the other element or layer, or another element or layer may be interposed therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, the present disclosure will be described in detail with reference to accompanying drawings.

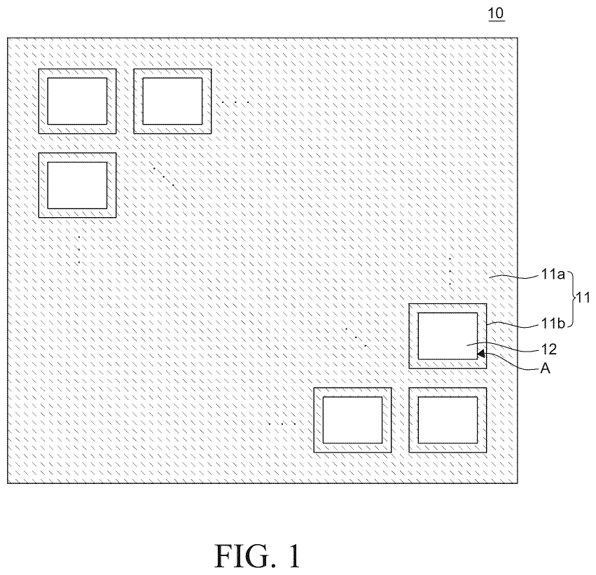

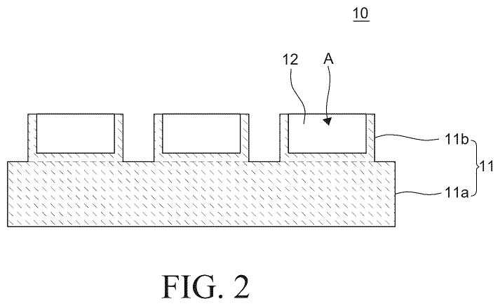

FIG. 1 is a plan view of an interposer according to an exemplary embodiment of the present disclosure. FIG. 2 is a cross-sectional view of an interposer according to an exemplary embodiment of the present disclosure.

Referring to FIGS. 1 and 2, an interposer 10 is a member which transfers a plurality of light emitting diodes to a target substrate. The interposer 10 may transport a plurality of light emitting diodes disposed on a wafer or a temporary substrate to a target substrate, such as a substrate of a display device. For example, in a non-contact state of the wafer or the temporary substrate and the interposer 10, the laser process is performed on the wafer or the temporary substrate to transfer the plurality of light emitting diodes to the interposer 10. However, the present disclosure is not limited thereto and the interposer 10 may be brought into contact with an upper portion of the wafer or the temporary substrate on which the plurality of light emitting diodes are disposed to transfer the plurality of light emitting diodes to the interposer 10. Further, the interposer 10 on which the plurality of light emitting diodes are temporarily attached is bonded to the target substrate to transfer the plurality of light emitting diodes to the target substrate. Therefore, the plurality of light emitting diodes are transferred from the temporary substrate to the target substrate using the interposer 10 to form an electronic product, such as a display device.

At this time, the light emitting diode may be a light emitting diode (LED) or a micro light emitting diode (micro LED).

The interposer 10 includes a mold 11 and a plurality of insulating members 12.

The mold 11 is a configuration for supporting various components included in the interposer 10. The mold 11 may be formed of a material that is harder than the insulating member 12 to minimize or reduce the bending of the insulating member 12 to be described below. The mold 11 supports the insulating member 12 which is more flexible than the mold 11 to minimize the deformation thereof during the transfer process. Further, the mold 11 is formed of a material having a coefficient of thermal expansion that is smaller than the coefficient of thermal expansion of the plurality of insulating members 12. For example, the mold 11 may be formed of glass or quartz.

The mold 11 includes a base portion 11a and a plurality of bumps 11b which are spaced apart from each other on the base portion 11a.

Referring to FIG. 2, the base portion 11a is a lower portion of the mold 11 and is below the bumps 11B. The base portion 11a may support the plurality of bumps 11b. The bumps 11b are protrusions that protrude away from the base portion 11a. Thus, the base portion 11a includes a plurality of protrusions. As shown in FIG. 2, the bumps 12 extend from an upper surface of the mold 11 in a direction away from the upper surface of the base portion 11a. The base portion 11a has a flat shape, but is not limited thereto.

Referring to FIGS. 1 and 2, the plurality of bumps 11b are disposed on the base portion 11a and the plurality of bumps 11b may be disposed to be spaced apart from each other. For example, the plurality of bumps 11b may be disposed in a matrix on the base portion 11a. The plurality of bumps 11b is formed of the same material as the base portion 11a and is integrally formed with the base portion 11a.

Each of the plurality of bumps 11b may include an accommodation unit A. The accodation unit A is a cavity that is configured to contain a light emitting diode as will be further described below, in one embodiment. For example, referring to FIG. 2, each of the plurality of bumps 11b may include a bottom surface and a side wall which define an accommodation unit A (e.g., the cavity). The bottom surface of each of the plurality of bumps 11b has a flat surface and the side wall surrounds the bottom surface to define the accommodation unit A. For example, each of the plurality of bumps 11b may correspond to a cup shape.

In the meantime, a size of each accommodation unit A may correspond to a size of each of the plurality of light emitting diodes to be described below. For example, one accommodation unit A may have a size enough to accommodate one light emitting diode.

The interposer 10 may include a plurality of insulating members 12. Each of the plurality of insulating members 12 may be disposed in a corresponding one of the plurality of bumps 11b. For example, each of the plurality of insulating members 12 may be disposed in the accommodation unit A of a corresponding one of the plurality of bumps 11b. Accordingly, a size of one insulating member 12 may correspond to a size of one accommodation unit A.

The plurality of insulating members 12 may be a material which temporarily attaches the plurality of light emitting diodes to the mold 11 during a process of transferring the plurality of light emitting diodes to a target substrate. For example, during the process of transferring the plurality of light emitting diodes to the target substrate, the plurality of light emitting diodes may be fixed to the plurality of insulating members 12 and may be temporarily attached to the mold 11 by means of the plurality of insulating members 12.

Each of the plurality of insulating members 12 may be formed of a material having viscoelasticity and adhesiveness such as a gel. For example, the plurality of insulating members 12 may be formed of liquid silicon, poly dimethyl siloxane (PDMS), poly urethane acrylate (PUA), polyethylene glycol (PEG), polymethylmethacrylate (PMMA), polystyrene (PS), epoxy resin, urethane resin, or acrylic resin, but is not limited thereto.

The plurality of insulating members 12 may be transferred to the target substrate together with the plurality of light emitting diodes during the process of transferring the plurality of light emitting diodes to the target substrate.

In the meantime, the plurality of insulating members 12 may include a material which improves the efficiency of the plurality of light emitting diodes and easily converts the colors. For example, the plurality of insulating members 12 may include a light diffuser, such as scattering particles, a photo conversion material and/or a fluorescent material. Thus, the insulating member 12 diffuses light emitting by the light emitting diodes.

At this time, each of the plurality of insulating members 12 may include different types of scattering particles, a photo conversion material and/or a fluorescent material. For example, adjacent insulating members 12, among the plurality of insulating members 12, may include different types of scattering particles, a photo conversion material and/or a fluorescent material. Specifically, a light emitting diode which emits one color is disposed in one insulating member 12 and a light emitting diode which emits different color light is disposed in the other adjacent insulating member 12. For example, a red light emitting diode, a green light emitting diode, and a blue light emitting diode may be sequentially disposed along a row direction and/or a column direction. Accordingly, among the plurality of insulating members 12, a plurality of insulating members 12 in which a red light emitting diode is disposed may include a material which improves a luminous efficiency of the red light emitting diode. Among the plurality of insulating members 12, a plurality of insulating members 12 in which a green light emitting diode is disposed may include a material which improves a luminous efficiency of the green light emitting diode. Among the plurality of insulating members 12, a plurality of insulating members 12 in which a blue light emitting diode is disposed may include a material which improves the luminous efficiency of the blue light emitting diode. However, the present disclosure is not limited thereto and all the plurality of insulating members 12 may include the same type of scattering particles, photo conversion material and/or fluorescent material. As another exemplary embodiment, in the plurality of insulating members 12, light emitting diodes which emit the same color light may be disposed, and adjacent insulating members 12 include photo conversion materials which convert light to light of different colors, so that light of different colors may be emitted.

In the meantime, even though it is not illustrated in the drawing, the interposer 10 may further include a plurality of alignment bumps, a plurality of alignment patterns, and a plurality of displacement measurement areas which are used for an alignment process with a temporary substrate or a target substrate. For example, during the process of aligning the interposer 10 and the temporary substrate or the target substrate, an alignment key disposed on the temporary substrate or the target substrate is transferred to the plurality of alignment bumps of the interposer 10. Alternatively, the alignment pattern of the temporary substrate or the target substrate may be aligned in the plurality of alignment patterns of the interposer 10. Further, in the displacement measurement area of the interposer 10, laser passes through the interposer 10 to measure a parallelism of the interposer 10.

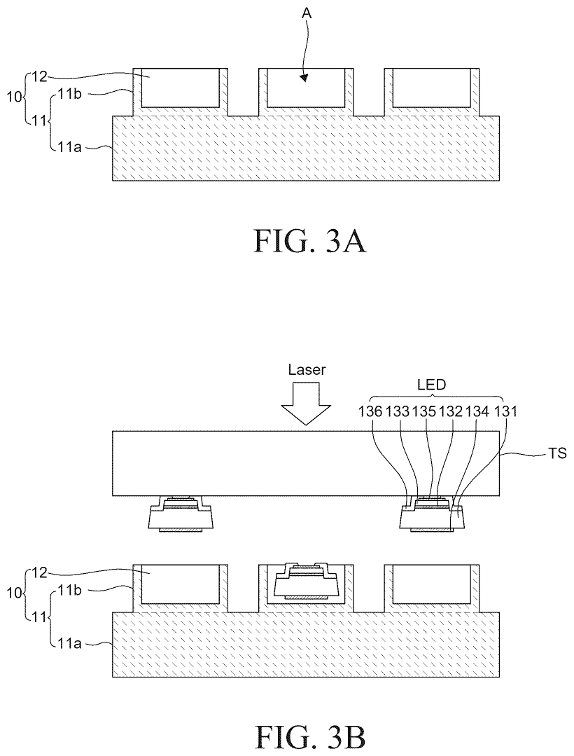

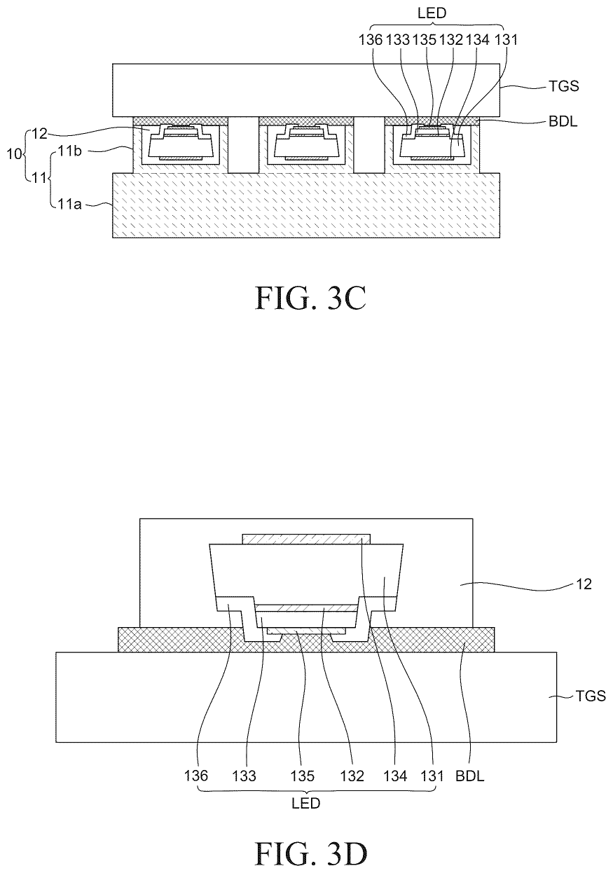

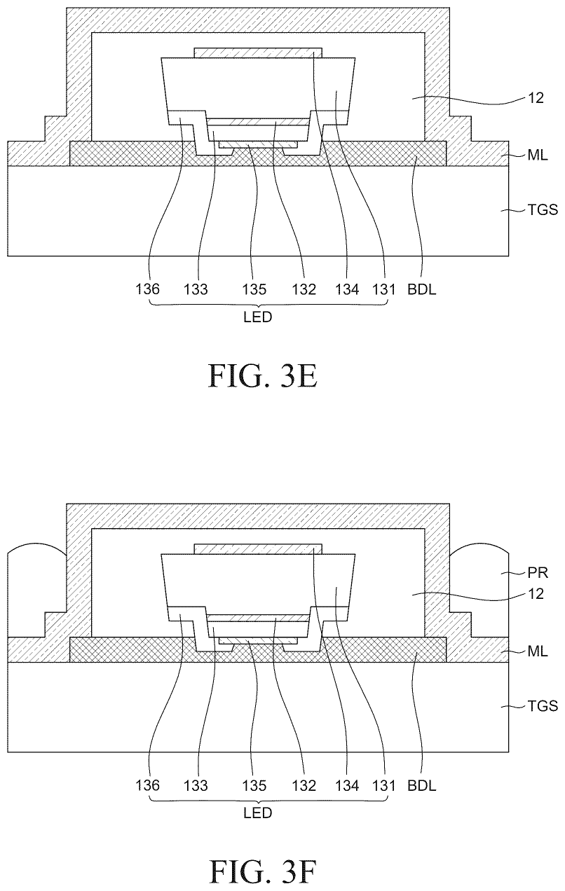

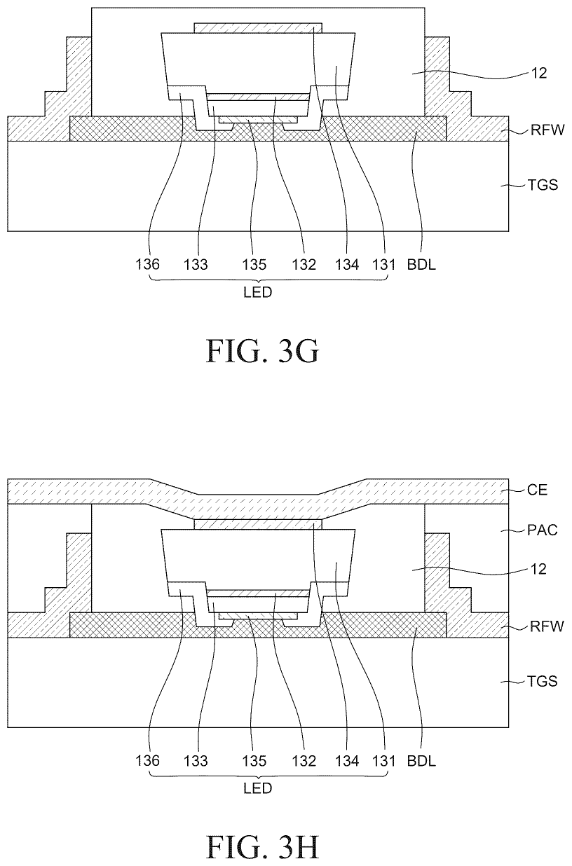

Hereinafter, a manufacturing process of a display device using an interposer 10 according to an exemplary embodiment of the present disclosure will be described with reference to FIGS. 3A to 3H.

FIGS. 3A to 3H are schematic diagrams for explaining a method for manufacturing a display device using an interposer according to an exemplary embodiment of the present disclosure.

First, referring to FIG. 3A, the plurality of insulating members 12 is filled in the mold 11 to form the interposer 10. Specifically, the plurality of insulating members 12 is formed to be filled in each of the plurality of accommodation units A of the plurality of bumps 11b of the mold 11.

Referring to FIG. 3B, after placing the temporary substrate TS on which the plurality of light emitting diodes LED are disposed on the interposer 10, the plurality of light emitting diodes LED on the temporary substrate TS is transferred to the interposer 10. At this time, the plurality of light emitting diodes LED may be disposed so as to correspond to the plurality of accommodation units A defined by the plurality of bumps 11b. At this time, on the temporary substrate TS, one light emitting diode LED may be disposed so as to correspond to one accommodation unit A. Accordingly, in one accommodation unit A, only a light emitting diode LED which emits one color light, among the plurality of light emitting diodes LED, may be disposed.

In the meantime, the transfer process of the light emitting diode LED may be performed in a non-contact state of the interposer 10 and the temporary substrate TS. For example, in a state in which the interposer 10 and the temporary substrate TS are spaced apart from each other, a process of irradiating laser to the temporary substrate TS may be performed. At this time, the temporary substrate TS may be a wafer on which the plurality of light emitting diodes LED is formed. Accordingly, the plurality of light emitting diodes LED which are attached to the temporary substrate TS may be dropped from the temporary substrate TS to the interposer 10. For example, an adhesive layer (not illustrated) which attaches the plurality of light emitting diodes LED to the temporary substrate TS may be disposed between the temporary substrate TS and the plurality of light emitting diodes LED. At this time, the adhesive layer may be formed of a material which loses the adhesive strength by the laser process. Accordingly, in an area which is irradiated with the laser, the plurality of light emitting diodes LED are detached from the temporary substrate TS and the plurality of light emitting diodes LED detached from the temporary substrate TS are dropped to be seated in the interposer 10.

In the meantime, during the process of transferring the plurality of light emitting diodes LED to the interposer 10, the plurality of light emitting diodes LED may be seated in the plurality of accommodation units A. At this time, some of the plurality of light emitting diodes LED disposed in the plurality of accommodation units A may be surrounded by the plurality of insulating members 12. Further, the other of the plurality of light emitting diodes LED are exposed from the plurality of insulating members 12.

Specifically, each of the plurality of light emitting diodes LED includes a first semiconductor layer 131, an emission layer 132, a second semiconductor layer 133, a first electrode 134, a second electrode 135, and an encapsulation film 136.

The first semiconductor layer 131 and the second semiconductor layer 133 are disposed with the emission layer 132 therebetween and each of the first semiconductor layer 131 and the second semiconductor layer 133 may be a layer formed by doping p-type and n-type impurities into a specific material. For example, the first semiconductor layer 131 and the second semiconductor layer 133 may be layers formed by doping p-type and n-type impurities into a material, such as gallium nitride (GaN), indium aluminum phosphide (InAlP), or gallium arsenide (GaAs). The n-type impurity may be silicon (Si), germanium (Ge), and tin (Sn), and the p-type impurity may be magnesium (Mg), zinc (Zn), and beryllium (Be), but are not limited thereto.

The emission layer 132 is disposed between the first semiconductor layer 131 and the second semiconductor layer 133. The emission layer 132 is supplied with holes and electrons from the first semiconductor layer 131 and the second semiconductor layer 133 to emit light. The emission layer 132 may be formed by a single layer or a multi-quantum well (MQW) structure, and for example, may be formed of indium gallium nitride (InGaN) or gallium nitride (GaN), but is not limited thereto.

The first electrode 134 is disposed below the first semiconductor layer 131 and the second electrode 135 may be disposed on the second semiconductor layer 133. The first electrode 134 and the second electrode 135 may be configured by an opaque conductive material, such as titanium (Ti), gold (Au), silver (Ag), copper (Cu) or an alloy thereof, a transparent conductive material, such as indium tin oxide (ITO) or indium zinc oxide (IZO), or a combination of the opaque conductive material and the transparent conductive material. However, the materials of the first electrode and the second electrode are not limited thereto. In the meantime, an electrode which is disposed in a direction in which light is emitted, of the first electrode 134 and the second electrode 135, may be formed of a transparent conductive material. For example, when light emitted from the emission layer 132 travels to the first electrode 134, the first electrode 134 may be configured by a transparent conductive material, such as indium tin oxide (ITO) or indium zinc oxide (IZO), but is not limited thereto.

The encapsulation film 136 which covers at least a part of the first semiconductor layer 131, the emission layer 132, and the second semiconductor layer 133 is disposed. The encapsulation film 136 is formed of an insulating material to protect the first semiconductor layer 131, the emission layer 132, and the second semiconductor layer 133. The encapsulation film 136 may cover a side surface of the first semiconductor layer 131, a side surface of the emission layer 132, and a side surface of the second semiconductor layer 133. Further, the first electrode 134 and the second electrode 135 may be exposed from the encapsulation film 136. The encapsulation film 136 may be formed of any one of insulating materials, such as silicon oxide (SiOx) or silicon nitride (SiNx), but is not limited thereto.

At this time, the first electrode 134, the first semiconductor layer 131, the emission layer 132, and the second semiconductor layer 133 of the plurality of light emitting diodes LED are disposed in the accommodation unit A to be surrounded by the insulating member 12. In contrast, the second electrode 135 of the plurality of light emitting diodes LED may be exposed from the insulating member 12. In the meantime, even though in FIG. 3B, it is illustrated that the second semiconductor layer 133 is surrounded by the insulating member 12, the present disclosure is not limited thereto and a part of the second semiconductor layer 133 may be exposed from the insulating member 12. For example, in the plurality of light emitting diodes LED transferred to the interposer 10, a part of an upper side of the second semiconductor layer 133 and the second electrode 135 may protrude to the outside of the accommodation unit A. The part of the upper side of the second semiconductor layer 133 and the second electrode 135 which protrude to the outside of the accommodation unit A may be exposed from the insulating member 12.

Referring to FIG. 3C, the target substrate TGS is disposed on the interposer 10 to which the plurality of light emitting diodes LED are attached and the plurality of light emitting diodes LED are transferred to the target substrate TGS.

The target substrate TGS may be a substrate used for a final product, such as a display device, to be manufactured using the interposer 10 and may include a plurality of circuits and a plurality of signal lines for driving the plurality of light emitting diodes LED.

The bonding layer BDL may be disposed on the target substrate TGS. At this time, the bonding layer BDL may fix (e.g., connect or attach) the plurality of light emitting diodes LED to the target substrate TGS. For example, a heat or a pressure may be applied to the target substrate TGS or the interposer 10 and the plurality of light emitting diodes LED and the plurality of insulating members 12 attached to the interposer 10 may be attached or bonded to the target substrate TGS by the heat or the pressure.

The plurality of bonding layers BDL may include a conductive material and electrically connect the target substrate TGS and the plurality of light emitting diodes LED. For example, during the process of transferring the plurality of light emitting diodes LED to the target substrate TGS, the plurality of light emitting diodes LED may be electrically connected to some configuration of the plurality of circuits and the plurality of signal lines of the target substrate TGS. For example, the second electrode 135 of each of the plurality of light emitting diodes LED exposed from the plurality of insulating members 12 may be electrically connected to the plurality of driving circuits disposed in the target substrate TGS through the bonding layer BDL. For example, the plurality of bonding layers BDL may be formed as ink or paste formed of silver (Ag) or carbon and a conductive material and may be formed as a film, such as an anisotropic conductive film (ACF).

Hereinafter, for the convenience of description, a partial area of the target substrate TGS on which one light emitting diode LED is disposed is enlarged.

Referring to FIG. 3D, after attaching and bonding the interposer 10 to the target substrate TGS, the mold 11 of the interposer 10 is separated from the target substrate TGS. At this time, the plurality of light emitting diodes LED and the plurality of insulating members 12 are transferred to the target substrate TGS and the mold 11 of the interposer 10 may be separated from the target substrate TGS. During the process of attaching and bonding the plurality of insulating members 12 to the target substrate TGS, the plurality of insulating members 12 which surround the plurality of light emitting diodes LED may maintain a strong adhesive strength with the target substrate TGS and have a relatively weak adhesive strength with the mold 11. Accordingly, in the process of transferring the plurality of light emitting diodes LED attached to the interposer 10 to the target substrate TGS, the plurality of insulating members 12 of the interposer 10 are separated from the mold 11 and may maintain an attached state with the target substrate TGS.

Thereafter, a process of curing the plurality of insulating members 12 transferred to the target substrate TGS by irradiating ultra violet (UV) light or heat (e.g., thermal) to the target substrate TGS may be performed. In the meantime, the mold 11 from which the plurality of insulating members 12 is detached, together with the plurality of light emitting diodes LED may be reused to transfer the plurality of light emitting diodes LED to another target substrate TGS. For example, after the process of transferring the plurality of light emitting diodes LED to the target substrate TGS, the accommodation unit A of the mold 11 is filled with the insulating member 12 again to perform a process of forming the interposer 10. For example, the processes of FIGS. 3A to 3D are repeated with one mold 11 to transfer the plurality of light emitting diodes LED to the target substrate TGS.

Referring to FIG. 3E, in order to form a reflection layer which surrounds the plurality of light emitting diodes LED, a metal layer ML is formed on the plurality of light emitting diodes LED and the plurality of insulating members 12. The metal layer ML may be formed so as to correspond to the entire surface of the target substrate TGS. Therefore, the metal layer ML covers a top surface and a side surface of the plurality of insulating members 12 and may cover a top surface of the target substrate TGS exposed in an area between the plurality of insulating members 12. The metal layer ML may be formed of a metal material having an excellent reflective property, such as aluminum (Al), silver (Ag), copper (Cu), palladium (Pd), or an alloy thereof, but is not limited thereto.

Thereafter, a process of patterning a metal layer ML is performed. Referring to FIG. 3F, a photo resist PR is applied so as to cover a partial area of the metal layer ML. The photo resist PR may be used as a mask of the metal layer ML. For example, the photo resist PR surrounds the metal layer ML which is disposed on the side surface of the plurality of insulating members 12 and may be disposed to expose the metal layer ML disposed on the top surface of the plurality of insulating members 12. In the meantime, a thickness of the photo resist PR may be smaller than a thickness of the plurality of insulating members 12. Accordingly, a lower portion of the metal layer ML disposed on the side surface of the plurality of insulating members 12 may be covered by the photo resist PR and an upper portion may be exposed by the photo resist PR. In the meantime, even though it is not illustrated in the drawing, the photo resist PR may expose a partial area of the metal layer ML which is in contact with the top surface of the target substrate TGS. For example, the photo resist PR may be formed as a plurality of pattern shapes which surrounds the plurality of insulating members 12 on the target substrate TGS.

Referring to FIG. 3G, thereafter, a reflective side wall RFW is formed by removing the metal layer ML disposed in an area which does not overlap the photo resist PR. For example, a metal layer ML disposed on the plurality of insulating members 12 and a metal layer ML disposed on an upper side surface of the plurality of insulating members 12, among the metal layers ML, may be removed. Therefore, the top surface of the plurality of insulating members 12 and the upper side surface of the plurality of insulating members 12 may be exposed. Thereafter, the photo resist PR is removed to expose the reflective side wall RFW. In the meantime, even though it is not illustrated in the drawing, when the photo resist PR is formed to expose a partial area of the metal layer ML disposed between the plurality of insulating members 12, the reflective side wall RFW may be formed to be spaced apart from each other between the plurality of insulating members 12. That is, a plurality of reflective side walls RFW which surrounds the plurality of insulating members 12 may be formed on the target substrate TGS to be spaced apart from each other. The reflective side wall RFW covers the side surfaces of the plurality of insulating members 12 on the target substrate TGS and is disposed to surround the plurality of light emitting diodes LED to improve the luminous efficiency of the plurality of light emitting diodes LED transferred to the target substrate TGS.

Referring to FIG. 3H, a connection electrode CE which electrically connects the first electrode 134 of the light emitting diode LED and the target substrate TGS is formed. First, the planarization layer PAC is formed on the reflective side wall RFW and the target substrate TGS to planarize the top surface of the target substrate TGS. The planarization layer PAC is formed so as to cover the side surfaces of the plurality of insulating members 12. At this time, the thickness of the planarization layer PAC may correspond to the thickness of the plurality of insulating members 12. Further, the planarization layer PAC covers the top surface and the side surface of the reflective side wall RFW and may cover the upper side surface of the plurality of insulating members 12 exposed from the reflective side wall RFW. Thereafter, a process of exposing one surface of the first electrode 134 by removing a portion of the plurality of insulating members 12 disposed above the first electrodes 134 of the plurality of light emitting diodes LED is performed. Thereafter, the connection electrode CE is formed on the planarization layer PAC, the plurality of insulating members 12, and the first electrode 134 to electrically connect the plurality of light emitting diodes LED and the plurality of circuits and the plurality of signal lines of the target substrate TGS. The connection electrode CE may cover the top surface of the first electrode 134 exposed from the plurality of insulating members 12 and extend from a top surface of the first electrode 134 to cover top surfaces of the plurality of insulating members 12 and the planarization layer PAC. In the meantime, the planarization layer PAC may include a contact hole which exposes the plurality of circuits and the plurality of signal lines of the target substrate TGS and the connection electrode CE may be filled in the contact hole of the planarization layer PAC. Therefore, the connection electrode CE may electrically connect the plurality of light emitting diodes LED and some configuration of the plurality of circuits and the plurality of signal lines of the target substrate TGS. For example, the first electrode 134 of each of the plurality of light emitting diodes LED may be electrically connected to the plurality of power lines disposed on the target substrate TGS through the connection electrode CE.

In the related art, an interposer which temporarily attaches the plurality of light emitting diodes to transfer the plurality of light emitting diodes to the target substrate is used. For example, as an adhesive layer of the interposer, a material having viscoelasticity and adhesiveness is used. For example, the adhesive layer is formed of a PDMS based material. However, the PDMS based material has a high coefficient of thermal expansion. Specifically, a coefficient of thermal expansion of the PDMS based material is approximately 310 μm/m° C. Accordingly, when the adhesive layer is formed of a PDMS based material, the misalignment of the light emitting diode may be more aggravated due to the temperature deviation occurring during the transfer process of the light emitting diode. Specifically, in the case of the high resolution display device, each pixel has a pitch of tens to hundreds of μm. Therefore, in the case of the high resolution display device, even small error causes problems with a transfer precision and a quality of the final product is also degraded.

Accordingly, in the interposer 10 according to the exemplary embodiment of the present disclosure and the method of manufacturing a display device using the interposer 10, the interposer 10 includes a mold 11 including a plurality of accommodation units A and a plurality of insulating members 12 to which a plurality of light emitting diodes LED is fixed. At this time, the mold 11 is formed of a material having a coefficient of thermal expansion smaller than that of the plurality of insulating members 12 and the plurality of insulating member 12 having a large coefficient of thermal expansion may be disposed only in the plurality of accommodation units A. Accordingly, as compared with an example that the insulating member to which the plurality of light emitting diodes is fixed is disposed on the entire surface of the interposer, an area of the insulating member 12 having a large coefficient of thermal expansion is reduced. Therefore, the mold 11 having a smaller coefficient of thermal expansion has a small deviation even by the temperature change so that the change of the interposer 10 may be small. Accordingly, in the interposer 10 according to the exemplary embodiment of the present disclosure and the method of manufacturing a display device using the interposer 10, the problem of the misalignment caused by the temperature change may be minimized and the transfer precision of the light emitting diode LED may be improved. As a result, the degradation of the quality of the final product may be suppressed.

In the meantime, in the related art, a contact transfer method is used to transfer the plurality of light emitting diodes to the target substrate. For example, a transfer method of transferring the plurality of light emitting diodes by attaching and pressurizing the plurality of light emitting diodes attached to the temporary substrate to the interposer and attaching and pressurizing the plurality of light emitting diodes attached to the interposer to the target substrate was used. Accordingly, in the case of the contact transfer method, all light emitting diodes disposed on the temporary substrate were in contact with one surface of the interposer and all light emitting diodes disposed on the temporary substrate were transferred to the interposer. At this time, in the case of the contact transfer method, the plurality of light emitting diodes disposed on the interposer was disposed along the alignment of the light emitting diodes disposed on the temporary substrate. Accordingly, when as the temporary substrate, a growth substrate on which the light emitting diode is formed was used or the light emitting diode attached to the temporary substrate is disposed along the alignment of the light emitting diodes formed on the growth substrate, the light emitting diode disposed on the target substrate may also have the same alignment as the alignment of the light emitting diodes disposed on the growth substrate. Therefore, a mura defect occurring in accordance with the position distribution of the light emitting diodes on the growth substrate may also be visible from the target substrate.

In contrast, the interposer 10 according to the exemplary embodiment of the present disclosure and the method of manufacturing a display device using the interposer 10 uses a contactless transfer method during which the interposer and the temporary substrate TS are not in contact with each other while light emitting diodes LED are transferred to insulating members. In the interposer 10 according to the exemplary embodiment of the present disclosure and the method of manufacturing a display device using the interposer 10, only some light emitting diode LED, among the plurality of light emitting diodes LED disposed on the temporary substrate TS, may be transferred to the interposer 10. Accordingly, in the interposer 10 according to the exemplary embodiment of the present disclosure and the method of manufacturing a display device using the interposer 10, a plurality of light emitting diodes LED formed on one growth substrate are uniformly dispersed to be disposed on the target substrate TGS. Therefore, even though the plurality of light emitting diodes LED attached to the interposer 10 is transferred to the target substrate TGS, the mura defect of the plurality of light emitting diodes LED which is caused according to the position of the growth substrate may be suppressed from being visible from the target substrate TGS.

Further, in the interposer 10 according to the exemplary embodiment of the present disclosure and the method of manufacturing a display device using the interposer 10, a contactless transfer method is used so that even though the light emitting diode LED is transferred to a partial area of the interposer 10, another light emitting diode LED may be transferred to the same interposer 10. For example, in the case of the contact transfer method, when the light emitting diode is transferred to a partial area of the interposer, there may be a problem in that the transferred light emitting diode interferes with another light emitting diode attached to the temporary substrate. In contrast, in the case of the contactless transfer method, even though the light emitting diode LED attached to the temporary substrate TS or the wafer is disposed in a position overlapping the light emitting diode LED transferred to the interposer 10, the transfer process may be performed in a state in which the light emitting diode LED attached to the temporary substrate TS or the wafer is spaced apart from the light emitting diode LED transferred to the interposer 10. Accordingly, a light emitting diode LED transferred from the plurality of temporary substrate TS or the plurality of wafers may be disposed on one interposer 10. Therefore, the interposer 10 having an area larger than the temporary substrate TS or the wafer may be used. Accordingly, as compared with the contact transfer method, the number of transfer processes of the plurality of light emitting diodes LED may be reduced, thereby implementing the process optimization.

Further, in the interposer 10 according to the exemplary embodiment of the present disclosure and the method of manufacturing a display device using the interposer 10, a material having material having viscoelasticity and adhesiveness, such as a gel, is used for the plurality of insulating members 12 to reduce an impact to be applied to the plurality of light emitting diodes LED during the contactless transferring. In the interposer 10 according to the exemplary embodiment of the present disclosure and the method of manufacturing a display device using the interposer 10, a contactless transfer method by which the plurality of light emitting diodes LED attached to the temporary substrate TS or the wafer is dropped to the interposer 10 is used. Therefore, the plurality of light emitting diodes LED collides with the interposer 10 at a high speed so that an impact may be applied to the plurality of light emitting diodes LED. At this time, the plurality of insulating members 12 formed of a gel material having fluidity accommodates the plurality of light emitting diodes LED to reduce the impact applied to the plurality of light emitting diodes LED.

Further, in the interposer 10 according to the exemplary embodiment of the present disclosure and the method of manufacturing a display device using the interposer 10, the plurality of insulating members 12 include scattering particles, a photo conversion material and/or a fluorescent material and is transferred to the target substrate TGS together with the plurality of light emitting diodes LED. Accordingly, as compared with the example that an insulating material including scattering particles, a photo conversion material and/or a fluorescent material is separately formed on the plurality of light emitting diodes LED transferred to the target substrate TGS, the manufacturing process is simplified so that the process optimization may be implemented.

Further, in the interposer 10 according to the exemplary embodiment of the present disclosure and the method of manufacturing a display device using the interposer 10, the reflective side wall RFW which surrounds the plurality of light emitting diodes LED transferred to the target substrate TGS and the plurality of insulating members 12 are formed to improve the luminous efficiency of the plurality of light emitting diodes LED transferred to the target substrate TGS.

Further, in the interposer 10 according to the exemplary embodiment of the present disclosure and the method of manufacturing a display device using the interposer 10, the plurality of bumps 11b of the interposer 10 are disposed to be spaced apart from each other on the base portion 11a. Accordingly, during the process of bonding and transferring the plurality of light emitting diodes LED fixed to the interposer 10 to the target substrate TGS, the plurality of bumps 11b is in contact with the target substrate TGS and a space between the plurality of bumps 11b may not be in contact with the target substrate TGS. Accordingly, when the plurality of light emitting diodes LED fixed to the interposer 10 and the target substrate TGS are pressurized, the force may be applied only to the plurality of bumps 11b. Therefore, as compared with an example that the plurality of bumps of the interposer are connected to each other, a contact area with the target substrate TGS is reduced and a force applied to the plurality of bumps 11b per unit area may be increased. Therefore, a problem in that the plurality of light emitting diodes LED fixed to the interposer 10 is not transferred to the target substrate TGS may be reduced. Accordingly, in the interposer 10 according to the exemplary embodiment of the present disclosure and the method of manufacturing a display device using the interposer 10, the plurality of bumps 11b of the interposer 10 is disposed to be spaced apart from each other to improve the transfer precision of the light emitting diode LED.

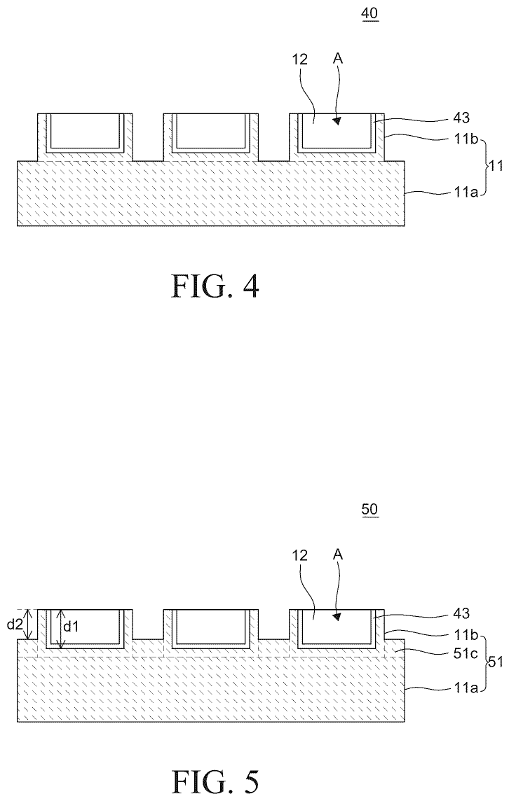

FIG. 4 is a cross-sectional view of an interposer according to another exemplary embodiment of the present disclosure. The only difference between an interposer 40 of FIG. 4 and the interposer 10 of FIGS. 1 to 3H is that a coating layer 43 is added, but the other configurations are substantially the same, so that a redundant description will be omitted.

Referring to FIG. 4, a coating layer 43 is disposed on the mold 11 of the interposer 40. The coating layer 43 may be disposed so as to cover a bottom surface and a side wall of each of the plurality of bumps 11b on the plurality of bumps 11b of the mold 11. The coating layer 43 may include at least one or more of indium tin oxide (ITO), Teflon, and fluorine materials.

In the meantime, even though in FIG. 4, it is illustrated that the coating layers 43 are spaced apart from each other between the plurality of bumps 11b, the present disclosure is not limited thereto and the coating layers 43 disposed in the plurality of bumps 11b may be integrally formed to be connected to each other.

In the interposer 40 according to another exemplary embodiment of the present disclosure and the method of manufacturing a display device using the interposer 40, a mold 11 of the interposer 40 including a plurality of accommodation units A is formed of a material having a coefficient of thermal expansion smaller than that of a plurality of insulating members 12 to which a plurality of light emitting diodes LED is fixed. Therefore, the misalignment problem according to the temperature change during the process of transferring the plurality of light emitting diodes LED may be minimized and the transfer precision of the light emitting diode LED may be improved.

In the interposer 40 according to another exemplary embodiment of the present disclosure and the method of manufacturing a display device using the interposer 40, the plurality of bumps 11b of the interposer 40 is disposed to be spaced apart from each other on the base portion 11a. Accordingly, during the process of transferring the plurality of light emitting diodes LED, a force applied to the plurality of bumps 11b per unit area is increased to improve the transfer precision of the light emitting diode LED. In the interposer 40 according to another exemplary embodiment of the present disclosure and the method of manufacturing a display device using the interposer 40, the coating layer 43 which covers the plurality of bumps 11b of the interposer 40 is included. The coating layer 43 may improve a releasing property of the plurality of insulating members 12 disposed in the accommodation units A of the plurality of bumps 11b and the plurality of bumps 11b. For example, when the releasing property of the plurality of insulating members 12 disposed in the accommodation units A and the plurality of bumps 11b is degraded, the plurality of insulating members 12 forms a strong adhesive strength with the mold 11 including the plurality of bumps 11b so that there may be a problem in that the transferring to the target substrate TGS is not made. Accordingly, there may be a problem in that the plurality of light emitting diodes LED surrounded by the plurality of insulating members 12 are not transferred to the target substrate TGS. Therefore, in the interposer 40 according to another exemplary embodiment of the present disclosure and the method of manufacturing a display device using the interposer 40, the coating layer 43 which improves the releasing property of the plurality of bumps 11b and the plurality of insulating members 12 is formed on the plurality of bumps 11b of the interposer 40 to improve the transfer success rate of the plurality of light emitting diodes LED.

FIG. 5 is a cross-sectional view of an interposer according to still another exemplary embodiment of the present disclosure. The interposer 50 of FIG. 5 is different from the interposer 40 of FIG. 4 in that a bridge 51c is added, but the other configurations are substantially the same so that a redundant description will be omitted.

Referring to FIG. 5, a mold 51 of the interposer 50 includes a bridge 51c disposed on the base portion 11a. The bridge 51c may connect the plurality of bumps 11b which is disposed to be spaced apart from each other on the base portion 11a. For example, the bridge 51c may be filled between the plurality of bumps 11b on the base portion 11a.

The bridge 51c is formed of the same material as the base portion 11a and the plurality of bumps 11b to be integrally formed with the base portion 11a and the plurality of bumps 11b. For example, the bridge 51c may be formed of glass or quartz.

In the meantime, a height of the side wall of a bump 11b protruding between adjacent bumps 11b may vary depending on a thickness of the bridge 51c. For example, a distance d1 between a bottom surface of the plurality of bumps 11b and a top surface of a side wall of the plurality of bumps 11b may be larger than a distance d2 between a top surface of the bridge 51c and the top surface of the side wall of the plurality of bumps 11b. Thus, the buttom surface of the bumps 11B extends into the bridge 51c. Further, the larger the thickness of the bridge 51c, the smaller the distance d2 between the top surface of the bridge 51c and the top surface of the side wall of the plurality of bumps 11b. For example, the thickness of the bridge 51c may correspond to the height of the side wall of the plurality of bumps 11b. Accordingly, the top surface of each of the plurality of bumps 11b is disposed on the same plane as the top surface of the bridge 51c and a transfer surface of the interposer 50 may be configured as a flat surface by a surface of the plurality of insulating members 12, a side surface of the plurality of bumps 11b, and a surface of the bridge 51c. Accordingly, during the process of transferring the plurality of light emitting diodes LED to the target substrate TGS, a contact area of the interposer 50 and the target substrate TGS is increased and a force applied to the plurality of bumps 11b per unit area may be reduced.

Further, in the interposer 50 according to another exemplary embodiment of the present disclosure and the method of manufacturing a display device using the interposer 50, the mold 51 of the interposer 50 includes the bridge 51c which connects the plurality of bumps 11b disposed to be spaced apart from each other. Therefore, a protruding height of the side wall of a bump 11b between adjacent bumps 11b may vary depending on a thickness of the bridge 51c. Therefore, the flatness of the transfer surface of the interposer 50 may be adjusted and a force applied to the plurality of bumps 11b per unit area is adjusted to easily adjust the transfer process of the light emitting diodes LED.

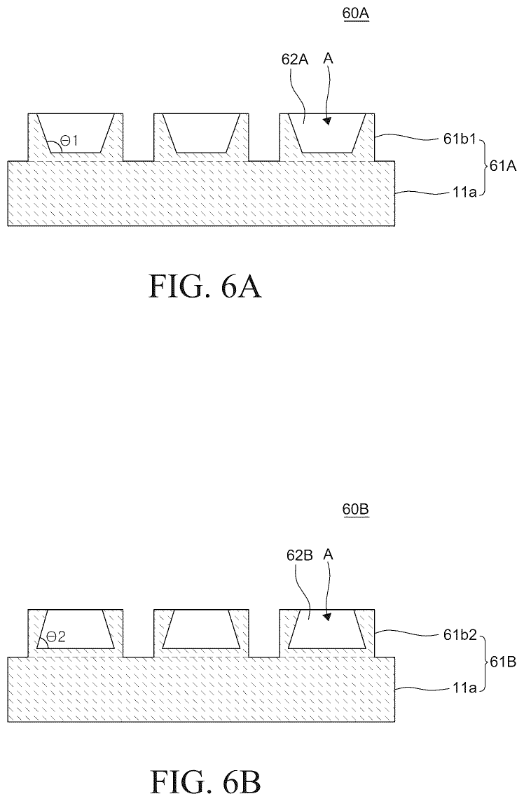

FIGS. 6A and 6B are cross-sectional views of an interposer according to still another exemplary embodiment of the present disclosure. The difference between an interposer 60A of FIG. 6A and the interposer 10 of FIGS. 1 to 3H is side walls of a plurality of bumps 61b1 and a plurality of insulating members 62A and the difference between an interposer 60B of FIG. 6B and the interposer 10 of FIGS. 1 to 3H is side walls of a plurality of bumps 61b2 and a plurality of insulating members 62B. However, the other configurations are substantially the same so that a redundant description will be omitted.

Referring to FIG. 6A, a mold 61A of the interposer 60A includes a plurality of bumps 61b1 disposed to be spaced apart from each other on the base portion 11a. Referring to FIG. 6A, an inner surface of the plurality of bumps 61b1 is inclined with respect to the bottom surface. For example, an angle θ1 between the inner surface and the bottom surface of the plurality of bumps 61b1 may be larger than 90°. For example, the inner surface of the plurality of bumps 61b1 which is connected to the bottom surface of the plurality of bumps 61b1 forms an obtuse angle with the bottom surface of the plurality of bumps 61b1. Accordingly, a cross-sectional shape of an accommodation unit A of each of the plurality of bumps 61b1 may be a trapezoidal shape.

Referring to FIG. 6A, a plurality of insulating members 62A may be disposed in the accommodation units A of the plurality of bumps 61b1 of the interposer 60A. The cross-sectional shape of the plurality of insulating members 62A may be a trapezoidal shape corresponding to the cross-sectional shape of the accommodation unit A of each of the plurality of bumps 61b1.

Referring to FIG. 6B, a mold 61B of the interposer 60B includes a plurality of bumps 61b2 disposed to be spaced apart from each other on the base portion 11a. Referring to FIG. 6B, an inner surface of the plurality of bumps 61b2 is inclined with respect to the bottom surface. For example, an angle θ2 between the inner surface and the bottom surface of the plurality of bumps 61b2 is smaller than 90°. That is, the inner surface of the plurality of bumps 61b2 connected to the bottom surface of the plurality of bumps 61b2 forms an acute angle with the bottom surface of the plurality of bumps 61b2.

Accordingly, a cross-sectional shape of an accommodation unit A of each of the plurality of bumps 61b2 may be a trapezoidal shape.

Referring to FIG. 6B, a plurality of insulating members 62B may be disposed in the accommodation unit A of each of the plurality of bumps 61b2 of the interposer 60B. The cross-sectional shape of the plurality of insulating members 62B may be a trapezoidal shape corresponding to the cross-sectional shape of the accommodation unit A of each of the plurality of bumps 61b2.

In the interposers 60A and 60B according to another exemplary embodiment of the present disclosure and the method of manufacturing a display device using the interposers 60A and 60B, molds 61A and 61B of the interposers 60A and 60B including a plurality of accommodation units A are formed of a material having a coefficient of thermal expansion smaller than that of a plurality of insulating members 62A and 62B to which a plurality of light emitting diodes LED is fixed. Therefore, the misalignment problem according to the temperature change during the process of transferring the plurality of light emitting diodes LED may be minimized and the transfer precision of the light emitting diode LED may be improved.

In the interposers 60A and 60B according to another exemplary embodiment of the present disclosure and the method of manufacturing a display device using the interposers 60A and 60B, the plurality of bumps 61b1 and 61b2 of the interposers 60A and 60B are disposed to be spaced apart from each other on the base portion 11a. Accordingly, during the process of transferring the plurality of light emitting diodes LED, a force applied to the plurality of bumps 61b1 and 61b2 per unit area is increased to improve the transfer precision of the light emitting diode LED.

In the interposers 60A and 60B according to another exemplary embodiment of the present disclosure and the method of manufacturing a display device using the interposers 60A and 60B, inner surfaces of the plurality of bumps 61b1 and 61b2 connected to the bottom surfaces of the plurality of bumps 61b1 and 61b2 are inclined with respect to the bottom surfaces of the plurality of bumps 61b1 and 61b2. For example, in the interposers 60A and 60B according to another exemplary embodiment of the present disclosure and the method of manufacturing a display device using the interposers 60A and 60B, an angle between the inner surface and the bottom surface of the plurality of bumps 61b1 and 61b2 is adjusted to adjust the transfer easiness of the plurality of light emitting diodes LED and the plurality of insulating members 62A and 62B. For example, when the mold 61A of the interposer 60A includes a plurality of bumps 61b1 in which the bottom surface and the inner surface form an obtuse angle, during the process of transferring the plurality of light emitting diodes LED to the target substrate TGS, the plurality of light emitting diodes LED and the plurality of insulating members 62A may be easily separated from the mold 61A. Further, when the mold 61B of the interposer 60B includes a plurality of bumps 61b2 in which the bottom surface and the inner surface form an acute angle, a fixing strength to fix the plurality of light emitting diodes LED and the plurality of insulating members 62B to the interposer 60B may be improved. Therefore, the plurality of light emitting diodes LED and the plurality of insulating members 62B may be suppressed from being easily separated from the interposer 60B. Accordingly, in the interposers 60A and 60B according to another exemplary embodiment of the present disclosure and the method of manufacturing a display device using the interposers 60A and 60B, an angle between the inner surface and the bottom surface of the plurality of bumps 61b1 and 61b2 is adjusted to adjust the transfer easiness of the plurality of light emitting diodes LED and the plurality of insulating members 62A and 62B.

In the interposers 60A and 60B according to another exemplary embodiment of the present disclosure and the method of manufacturing a display device using the interposers 60A and 60B, an angle between the inner surface and the bottom surface of the plurality of bumps 61b1 and 61b2 is adjusted to improve the luminous efficiency of the plurality of light emitting diodes LED. For example, when the plurality of light emitting diodes LED is transferred to the target substrate TGS together with the plurality of insulating members 62A and 62B, light emitted from the plurality of light emitting diodes LED passes through the plurality of insulating members 62A and 62B and may be refracted or reflected from an interface of the plurality of insulating members 62A and 62B. Accordingly, a shape of the plurality of insulating members 62A and 62B may be adjusted according to an angle between the inner surface and the bottom surface of the plurality of bumps 61b1 and 61b2 and the luminous efficiency of the plurality of light emitting diodes LED may be improved according to the shape of the plurality of insulating members 62A and 62B. Further, the plurality of reflective side walls RFW is disposed along a shape of the plurality of insulating members 62A and 62B. Therefore, the shape of the reflective side wall RFW may be adjusted according to an angle between the inner surface and the bottom surface of the plurality of bumps 61b1 and 61b2 and the luminous efficiency of the plurality of light emitting diodes LED may be improved according to the shape of the reflective side wall RFW. Accordingly, in the interposers 60A and 60B according to another exemplary embodiment of the present disclosure and the method of manufacturing a display device using the interposers 60A and 60B, an angle between the inner surface and the bottom surface of the plurality of bumps 61b1 and 61b2 is adjusted to improve the luminous efficiency of the plurality of light emitting diodes LED.

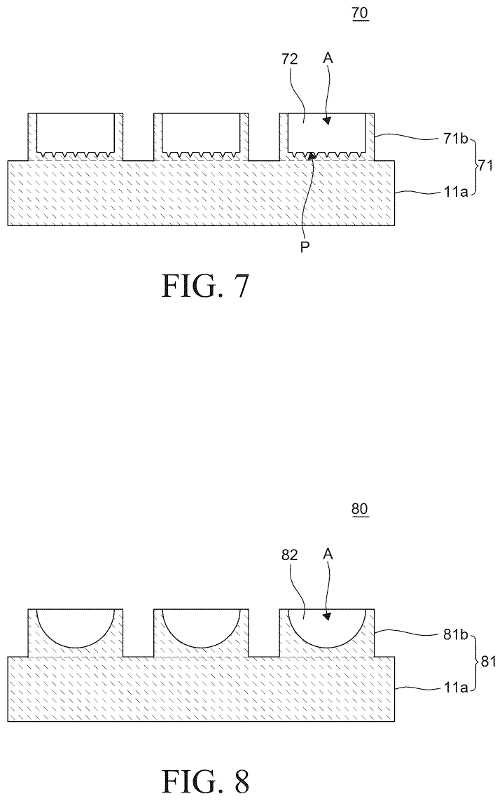

FIG. 7 is a cross-sectional view of an interposer according to still another exemplary embodiment of the present disclosure. The only difference between an interposer 70 of FIG. 7 and the interposer 10 of FIGS. 1 to 3H is that a plurality of bumps 71b is added to the mold 71 and a plurality of insulating members 72 is different, but the other configurations are substantially the same, so that a redundant description will be omitted.

Referring to FIG. 7, a bottom surface of each of the plurality of bumps 71b includes a plurality of patterns P. The plurality of patterns P may include a plurality of concave portions and/or a plurality of protrusions.

A plurality of insulating members 72 may be disposed in an accommodation unit A of each of a plurality of bumps 71b. The plurality of insulating members 72 may include a plurality of concave portions and/or a plurality of protrusions corresponding to the plurality of patterns P. For example, the plurality of insulating members 72 has a hexahedral shape formed by one surface including a plurality of concave portions and/or a plurality of protrusions and five flat surfaces, but is not limited thereto.

In the interposer 70 according to still another exemplary embodiment of the present disclosure and the method of manufacturing a display device using the interposer 70, a mold 71 of the interposer 70 including a plurality of accommodation units A is formed of a material having a coefficient of thermal expansion smaller than that of a plurality of insulating members 72 to which a plurality of light emitting diodes LED is fixed. Therefore, the misalignment problem according to the temperature change during the process of transferring the plurality of light emitting diodes LED may be minimized and the transfer precision of the light emitting diode LED may be improved.

In the interposer 70 according to still another exemplary embodiment of the present disclosure and the method of manufacturing a display device using the interposer 70, the plurality of bumps 71b of the interposer 70 is disposed to be spaced apart from each other on the base portion 11a. Accordingly, during the process of transferring the plurality of light emitting diodes LED, a force applied to the plurality of bumps 71b per unit area is increased to improve the transfer precision of the light emitting diode LED.

In the interposer 70 according to still another exemplary embodiment of the present disclosure and the method of manufacturing a display device using the interposer 70, bottom surfaces of the plurality of bumps 71b include a plurality of patterns P. Accordingly, the plurality of insulating members 72 disposed in the plurality of accommodation units A includes a plurality of concave portions and/or a plurality of protrusions corresponding to the plurality of patterns P. Therefore, light emitted from the plurality of light emitting diodes LED passes through the plurality of insulating members 72 and is refracted or reflected from the plurality of concave portions and/or the plurality of protrusions corresponding to the plurality of patterns P. Therefore, in the interposer 70 according to still another exemplary embodiment of the present disclosure and the method of manufacturing a display device using the interposer 70, the plurality of concave portions and/or the plurality of protrusions corresponding to the plurality of patterns P is formed in the plurality of insulating members 72 to improve the luminous efficiency of the plurality of light emitting diodes LED.

FIG. 8 is a cross-sectional view of an interposer according to still another exemplary embodiment of the present disclosure. The only difference between an interposer 80 of FIG. 8 and the interposer 10 of FIGS. 1 to 3H is a plurality of bumps 81b of a mold 81 and a plurality of insulating members 82, but the other configurations are substantially the same, so that a redundant description will be omitted.

Referring to FIG. 8, an inner surface of the plurality of bumps 81b is a curved surface. For example, the inner surface of each of the plurality of bumps 81b may be adjacent to the base portion 11a as it is closer to the center of each of the plurality of bumps 81b. For example, the inner surface of the plurality of bumps 81b may have a hemispherical shape or a semi-cylindrical shape, but is not limited thereto. The inner surfaces of the plurality of bumps 81b may define a plurality of accommodation units A. For example, each of the plurality of accommodation units A may have a hemispherical shape or a semi-cylindrical shape corresponding to the inner surface of the plurality of bumps 81b, but is not limited thereto.

The plurality of insulating members 82 may be disposed in the accommodation unit A of each of a plurality of bumps 81b. A shape of each of the plurality of insulating members 82 may correspond to a shape of the accommodation unit A of each of a plurality of bumps 81b. For example, the shape of each of the plurality of insulating members 82 may be a hemispherical shape or a semi-cylindrical shape, but is not limited thereto.

In the interposer 80 according to still another exemplary embodiment of the present disclosure and the method of manufacturing a display device using the interposer 80, a mold 81 of the interposer 80 including a plurality of accommodation units A is formed of a material having a coefficient of thermal expansion smaller than that of a plurality of insulating members 82 to which a plurality of light emitting diodes LED is fixed. Therefore, the misalignment problem according to the temperature change during the process of transferring the plurality of light emitting diodes LED may be minimized and the transfer precision of the light emitting diode LED may be improved.

In the interposer 80 according to still another exemplary embodiment of the present disclosure and the method of manufacturing a display device using the interposer 80, the plurality of bumps 81b of the interposer 80 is disposed to be spaced apart from each other on the base portion 11a. Accordingly, during the process of transferring the plurality of light emitting diodes LED, a force applied to the plurality of bumps 81b per unit area is increased to improve the transfer precision of the light emitting diode LED.

In the interposer 80 according to still another exemplary embodiment of the present disclosure and the method of manufacturing a display device using the interposer 80, inner surfaces of the plurality of bumps 81b are formed as curved surfaces. Accordingly, the shape of the plurality of insulating members 82 may vary according to the inner surface of the plurality of bumps 81b and the luminous efficiency of the plurality of light emitting diodes LED may be improved in accordance with the shape of the plurality of insulating members 82. Further, the shape of the reflective side wall RFW may vary according to the shape of the inner surface of the plurality of bumps 81b and the luminous efficiency of the plurality of light emitting diodes LED may be improved in accordance with the shape of the reflective side wall RFW.

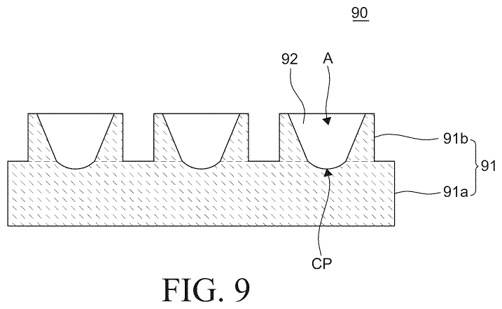

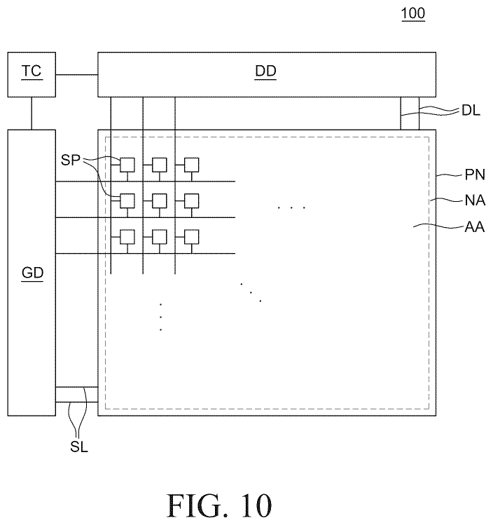

FIG. 9 is a cross-sectional view of an interposer according to still another exemplary embodiment of the present disclosure. The only difference between an interposer 90 of FIG. 9 and the interposer 10 of FIGS. 1 to 3H is that a base portion 91a of a mold 91 includes a plurality of concave patterns CP and a plurality of bumps 91b and a plurality of insulating members 92 are different. However, the other configurations are substantially the same, so that a redundant description will be omitted.

Referring to FIG. 9, a base portion 91a includes a plurality of concave patterns CP in an upper surface of the base portion 91a. The plurality of concave patterns CP overlap the accommodation units A. Each of the plurality of concave patterns CP may be disposed so as to correspond to each of the plurality of bumps 91b. For example, each of the plurality of concave patterns CP may be disposed in a center portion of each of the plurality of bumps 91b. The plurality of concave patterns CP may be a hemispherical shape or a semi-cylindrical shape, but is not limited thereto. Further, the thickness of the base portion 91a is reduced toward the center portion of the plurality of bumps 91b, but is not limited thereto. In the meantime, even though in FIG. 9, it is illustrated that the base portion 91a includes one concave pattern CP corresponding to one bump 91b, the present disclosure is not limited thereto and the base portion 91a may include a plurality of concave patterns CP corresponding to one bump 91b.

The plurality of bumps 91b is disposed on the base portion 91a. Each of the plurality of bumps 91b may be disposed so as to surround each of the plurality of concave patterns CP. For example, the inner surface of each of the plurality of bumps 91b may be connected to each of the plurality of concave patterns CP. For example, a cross-sectional shape of the inner surface of each of the plurality of bumps 91b may be formed as a straight line, but is not limited thereto and may be formed as a curved line.

The plurality of insulating members 92 may be disposed in an accommodation unit A of each of a plurality of bumps 91b and the plurality of concave patterns CP. A shape of each of the plurality of insulating members 92 may correspond to a shape of the accommodation unit A of each of a plurality of bumps 91b and a shape of the plurality of concave patterns CP. For example, each of the plurality of insulating members 92 may have a dome shape, but is not limited thereto.

In the interposer 90 according to still another exemplary embodiment of the present disclosure and the method of manufacturing a display device using the interposer 90, a mold 91 of the interposer 90 including a plurality of accommodation units A is formed of a material having a coefficient of thermal expansion smaller than that of a plurality of insulating members 92 to which a plurality of light emitting diodes LED is fixed. Therefore, the misalignment problem according to the temperature change during the process of transferring the plurality of light emitting diodes LED may be minimized and the transfer precision of the light emitting diode LED may be improved.

In the interposer 90 according to still another exemplary embodiment of the present disclosure and the method of manufacturing a display device using the interposer 90, the plurality of bumps 91b of the interposer 90 is disposed to be spaced apart from each other on the base portion 91a. Accordingly, during the process of transferring the plurality of light emitting diodes LED, a force applied to the plurality of bumps 91b per unit area is increased to improve the transfer precision of the light emitting diode LED.

In the interposer 90 according to still another exemplary embodiment of the present disclosure and the method of manufacturing a display device using the interposer 90, the base portion 91a includes a plurality of concave patterns CP and each of the plurality of bumps 91b is disposed so as to surround each of the plurality of concave patterns CP. Accordingly, a shape of each of the plurality of insulating members 92 corresponds to a shape of the accommodation unit A of each of a plurality of bumps 91b and a shape of the plurality of concave patterns CP. For example, each of the plurality of insulating members 92 may be formed to have a dome shape. Accordingly, the luminous efficiency of the plurality of light emitting diodes LED is improved in accordance with a shape of the plurality of insulating members 92 and the luminous efficiency of the plurality of light emitting diodes LED may be improved by adjusting a shape of a reflective side wall RFW disposed on the plurality of insulating members 92.

FIG. 10 is a schematic diagram of a display device according to an exemplary embodiment of the present disclosure. In FIG. 10, for the convenience of description, among various components of the display device 100, a display panel PN, a gate driver GD, a data driver DD, and a timing controller TC are illustrated.

Referring to FIG. 10, the display device 100 includes a display panel PN including a plurality of sub pixels SP, a gate driver GD and a data driver DD which supply various signals to the display panel PN, and a timing controller TC which controls the gate driver GD and the data driver DD.

A driver, such as a gate driver GD, a data driver DD, and a timing controller TC, may be connected to the display panel PN in various ways. For example, the gate driver GD may be mounted in the non-active area NA in a gate in panel (GIP) manner or mounted between the plurality of sub pixels SP in the active area AA in a gate in active area (GIA) manner.

The display panel PN is a configuration which displays images to the user and includes the plurality of sub pixels SP. In the display panel PN, the plurality of scan lines SL and the plurality of data lines DL intersect each other and the plurality of sub pixels SP are connected to the scan lines SL and the data lines DL, respectively. In addition, even though it is not illustrated in the drawing, each of the plurality of sub pixels SP may be connected to a high potential power line, a low potential power line, and a reference line.

In the display panel PN, an active area AA and a non-active area NA surrounding the active area AA may be defined.

The active area AA is an area in which images are displayed in the display device 100. In the active area AA, a plurality of sub pixels SP which configures a plurality of pixels PX and a circuit for driving the plurality of sub pixels SP may be disposed. The plurality of sub pixels SP are a minimum unit which configures the active area AA and n sub pixels SP may form one pixel PX. In each of the plurality of sub pixels SP, a light emitting diode and a thin film transistor for driving the light emitting diode may be disposed. The plurality of light emitting diodes may be defined in different manners depending on the type of the display panel PN. For example, when the display panel PN is an inorganic light emitting display panel, the light emitting diode may be a light emitting diode (LED) or a micro light emitting diode (LED).

In the active area AA, a plurality of signal lines which transmit various signals to the plurality of sub pixels SP are disposed. For example, the plurality of signal lines may include a plurality of data lines DL which supply a data voltage to each of the plurality of sub pixels SP and a plurality of scan lines SL which supply a gate voltage to each of the plurality of sub pixels SP. The plurality of scan lines SL extend to one direction in the active area AA to be connected to the plurality of sub pixels SP and the plurality of data lines DL extend to a direction different from the one direction in the active area AA to be connected to the plurality of sub pixels SP. In addition, in the active area AA, a low potential power line and a high potential power line may be further disposed, but are not limited thereto.

In the non-active area NA, images are not displayed, but a link line which transmits a signal to the sub pixel SP of the active area AA, a pad electrode, or a driving IC, such as a gate driver IC or a data driver IC, may be disposed.

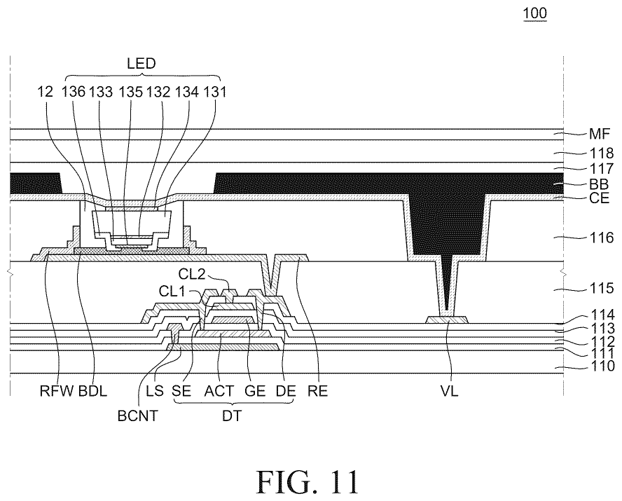

FIG. 11 is a cross-sectional view of a display device according to an exemplary embodiment of the present disclosure.

Referring to FIG. 11, the display panel PN includes a plurality of pixels which are formed by a plurality of sub pixels SP. Each of the plurality of sub pixels SP includes a light emitting diode LED and a pixel circuit to independently emit light. One pixel PX may include one or more first sub pixels, one or more second sub pixels, and one or more third sub pixels. For example, one pixel may include two first sub pixels, two second sub pixels, and two third sub pixels. At this time, the first sub pixel is a red sub pixel, the second sub pixel is a green sub pixel, and the third sub pixel may be a blue sub pixel, but it is not limited thereto.

Next, referring to FIG. 11 together, in each of the plurality of sub pixels SP of the display panel PN of the display device 100 according to the exemplary embodiment of the present disclosure, a substrate 110, a buffer layer 111, a gate insulating layer 112, a first interlayer insulating layer 113, a second interlayer insulating layer 114, a first planarization layer 115, a second planarization layer 116, a third planarization layer 117, a protection layer 118, an optical film MF, a black bank BB, a driving transistor DT, a light emitting diode LED, a plurality of reflection electrodes RE, a plurality of connection electrodes CE, a light shielding layer LS, an auxiliary electrode BCNT, a first conductive layer CL1, and a second conductive layer CL2 are disposed.

First, the substrate 110 is a component for supporting various components included in the display device 100 and may be formed of an insulating material. For example, the substrate 110 may be formed of glass or resin. Further, the substrate 110 may be configured to include a polymer or plastics or may be formed of a material having flexibility.

The light shielding layer LS is disposed in each of the plurality of sub pixels SP on the substrate 110. The light shielding layer LS blocks light incident onto an active layer ACT of the driving transistor DT to be described below from a lower portion the substrate 110. Light which is incident onto the active layer ACT of the driving transistor DT is blocked by the light shielding layer LS to minimize a leakage current.

The buffer layer 111 is disposed on the substrate 110 and the light shielding layer LS. The buffer layer 111 may reduce permeation of moisture or impurities through the substrate 110. For example, the buffer layer 111 may be configured by a single layer or a double layer of silicon oxide (SiOx) or silicon nitride (SiNx), but is not limited thereto. However, the buffer layer 111 may be omitted depending on a type of substrate 110 or a type of transistor, but is not limited thereto.

The driving transistor DT is disposed on the buffer layer 111. The driving transistor DT includes an active layer ACT, a gate electrode GE, a source electrode SE, and a drain electrode DE.

The active layer ACT is disposed on the buffer layer 111. The active layer ACT may be formed of a semiconductor material, such as an oxide semiconductor, amorphous silicon, or polysilicon, but is not limited thereto.

The gate insulating layer 112 is disposed on the active layer ACT. The gate insulating layer 112 is an insulating layer which insulates the active layer ACT from the gate electrode GE and may be configured by a single layer or a double layer of silicon oxide (SiOx) or silicon nitride (SiNx), but is not limited thereto.

The gate electrode GE is disposed on the gate insulating layer 112. The gate electrode GE may be configured by a conductive material, such as copper (Cu), aluminum (Al), molybdenum (Mo), nickel (Ni), titanium (Ti), chrome (Cr), or an alloy thereof, but is not limited thereto.

The first interlayer insulating layer 113 and the second interlayer insulating layer 114 are disposed on the gate electrode GE. In the first interlayer insulating layer 113 and the second interlayer insulating layer 114, a contact hole through which the source electrode SE and the drain electrode DE are connected to the active layer ACT is formed. The first interlayer insulating layer 113 and the second interlayer insulating layer 114 are insulating layers for protecting a component below the first interlayer insulating layer 113 and the second interlayer insulating layer 114 and may be configured by a single layer or a double layer of silicon oxide (SiOx) or silicon nitride (SiNx), but are not limited thereto.

The source electrode SE and the drain electrode DE which are electrically connected to the active layer ACT are disposed on the second interlayer insulating layer 114. The source electrode SE and the drain electrode DE may be configured by a conductive material, such as copper (Cu), aluminum (Al), molybdenum (Mo), nickel (Ni), titanium (Ti), chrome (Cr), or an alloy thereof, but are not limited thereto.

In the meantime, in the present specification, it is described that the first interlayer insulating layer 113 and the second interlayer insulating layer 114, that is, a plurality of insulating layers is disposed between the gate electrode GE and the source electrode SE and the drain electrode DE. However, only one insulating layer may be disposed between the gate electrode GE and the source electrode SE and the drain electrode DE, but is not limited thereto.

Further, as illustrated in the drawings, when a plurality of insulating layers, such as the first interlayer insulating layer 113 and the second interlayer insulating layer 114, is disposed between the gate electrode GE and the source electrode SE and the drain electrode DE, an electrode may be further formed between the first interlayer insulating layer 113 and the second interlayer insulating layer 114. The additionally formed electrode may form a capacitor with the other configuration disposed below first interlayer insulating layer 113 or above the second interlayer insulating layer 114.

For example, the first conductive layer CL1 is disposed between the first interlayer insulating layer 113 and the second interlayer insulating layer 114 and the second conductive layer CL2 which is electrically connected to the first conductive layer CL1 is disposed on the second interlayer insulating layer 114. The first conductive layer CL1 and the second conductive layer CL2 are disposed so as to overlap a gate electrode GE of a driving transistor DT to form a capacitor with the gate electrode GE of the driving transistor DT. Accordingly, various conductive layers, such as the first conductive layer CL1 and the second conductive layer CL2, are disposed on the substrate 110 to form a capacitor.

Next, the auxiliary electrode BCNT is disposed on the gate insulating layer 112. The auxiliary electrode BCNT is an electrode for applying a voltage to the light shielding layer LS below the buffer layer 111. For example, the light shielding layer LS is electrically connected to another configuration disposed on the substrate 110 by means of the auxiliary electrode BCNT to be applied with a voltage. The light shielding layer LS which is applied with a voltage by means of the auxiliary electrode BCNT does not operate as a floating gate and may minimize a fluctuation of a threshold voltage of the driving transistor DT which is generated by the floated light shielding layer LS.

A power line VL is disposed on the second interlayer insulating layer 114. The power line VL is electrically connected to the light emitting diode LED together with the driving transistor DT to allow the light emitting diode LED to emit light. The power line VL is a low potential power line, but is not limited thereto. The power line VL may be configured by a conductive material such as copper (Cu), aluminum (Al), molybdenum (Mo), nickel (Ni), titanium (Ti), chrome (Cr), or an alloy thereof, but is not limited thereto.

The first planarization layer 115 is disposed on the driving transistor DT and the power line VL. The first planarization layer 115 may planarize an upper portion of the substrate 110 on which the driving transistor DT is disposed. The first planarization layer 115 may be configured by a single layer or a double layer, and for example, may be formed of photo resist or an acrylic-based organic material, but is not limited thereto.

A plurality of reflection electrodes RE which are spaced apart from each other is disposed on the first planarization layer 115. The plurality of reflection electrodes RE are disposed below the plurality of light emitting diodes LED to be electrically connected to the plurality of light emitting diodes LED. The plurality of reflection electrodes RE are a configuration which reflects light emitted from the plurality of light emitting diodes LED to the top of the substrate 110 and are formed with a shape corresponding to each of the plurality of sub pixels SP. The plurality of reflection electrodes RE reflect the light emitted from the plurality of light emitting diodes LED and is also used as an electrode which electrically connects the plurality of light emitting diodes LED and the pixel circuit. Specifically, the plurality of reflection electrodes RE may be connected to the drain electrode DE of the driving transistor DT through a contact hole of the first planarization layer 115. That is, the plurality of reflection electrodes RE may electrically connect the second electrode 135 of the plurality of light emitting diodes LED and the driving transistor DT. The plurality of reflection electrodes RE are formed of a conductive material having excellent reflection property. For example, the plurality of reflection electrodes RE may be formed of a metal material having an excellent reflective property, such as aluminum (Al), silver (Ag), copper (Cu), palladium (Pd), or an alloy thereof, but is not limited thereto.

A plurality of bonding layers BDL may be disposed on the plurality of reflection electrodes RE. The plurality of bonding layers BDL may fix the plurality of light emitting diodes LED disposed on the plurality of reflection electrodes RE. For example, a bonding layer BDL is disposed between the reflective electrode RE and the second electrode 135 of the light emitting diode LED and the bonding layer BDL connects the reflective electrode RE to the second electrode 135 of the light emitting diode LED as shown in FIG. 11. Further, the plurality of bonding layers BDL may electrically connect the plurality of reflection electrodes RE and the second electrodes 135 of the plurality of light emitting diodes LED. The plurality of bonding layers BDL has been described in detail with reference to FIGS. 3A to 3F, so that a redundant description will be omitted. In the meantime, when a conductive material is separately disposed to electrically connect the plurality of reflection electrodes RE and the second electrodes 135 of the plurality of light emitting diodes LED, the plurality of bonding layers BDL may be formed of an insulating material.

The plurality of light emitting diodes LED may be disposed in each of the plurality of sub pixels SP on the plurality of bonding layers BDL. The plurality of light emitting diodes LED is disposed on the plurality of bonding layers BDL to be electrically connected to the reflection electrode RE. Specifically, the second electrodes 135 of the plurality of light emitting diodes LED and the reflection electrodes RE may be electrically connected by means of the plurality of bonding layers BDL.

The plurality of light emitting diodes LED is elements which emit light by a current and includes a first light emitting diode which emits red light, a second light emitting diode which emits green light, and a third light emitting diode which emits blue light and implements light with various colors including white by a combination thereof. For example, the light emitting diode LED may be a light emitting diode LED or a micro LED, but is not limited thereto.

The plurality of light emitting diodes LED may include a first semiconductor layer 131, an emission layer 132, a second semiconductor layer 133, a first electrode 134, a second electrode 135, and an encapsulation film 136. Hereinafter, it is assumed that the plurality of light emitting diodes LED has a lateral structure, but the type of the plurality of light emitting diodes LED is not limited thereto. The plurality of light emitting elements LED has been described in detail with reference to FIGS. 3A to 3F, so that a redundant description will be omitted.

A plurality of insulating members 12 which surrounds the plurality of light emitting diodes LED are disposed on the plurality of reflection electrodes RE. The plurality of insulating members 12 has been described in detail with reference to FIGS. 3A to 3F, so that a redundant description will be omitted. As shown in FIG. 11, an insulating member 12 surrounds side surfaces and a portion of an upper surface of the light emitting diode LED. In one embodient, the insulating member 12 is in direct contact with the bonding layer BDL.

A plurality of reflective side walls RFW which surrounds the plurality of light emitting diodes LED and the plurality of insulating members 12 are disposed on the plurality of reflection electrodes RE. The plurality of reflective side walls RFW are disposed on the reflective electrode RE and ends of the bonding layer BDL as shown in FIG. 11. In one embodiment, ends of the bonding layer BDL are in contact (e.g., direct contact) with the reflective side walls RFW that surround the LED and extend onto side surfaces of the insulating member 12. The plurality of reflective side walls RFW are configurations which reflect light which travels in a lateral direction, among light emitted from the plurality of light emitting diodes LED, to the top of the substrate 110 and may be disposed so as to surround the plurality of light emitting diodes LED. The plurality of reflective side walls RFW has been described in detail with reference to FIGS. 3A to 3F, so that a redundant description will be omitted.

The second planarization layer 116 is disposed on the plurality of reflection electrodes RE. The second planarization layer 116 is disposed so as to surround the plurality of light emitting diodes LED, the plurality of insulating members 12, and the plurality of reflective side walls RFW to fix and protect the plurality of light emitting diodes LED. In one emobdiment, the planarization layer is in direct contact with a portion of the side surface of the insulating layer 12 that is not surrounded by the reflective side walls RFW as shown in FIG. 11. The second planarization layer 116 may be configured by a single layer or a double layer, and for example, may be formed of photo resist or an acrylic-based organic material, but is not limited thereto.

The common electrode CE is disposed on the entire surface of the substrate 110 on the second planarization layer 116. The common electrode CE is an electrode which electrically connects the power line VL and the plurality of light emitting diodes LED. The common electrode CE may be electrically connected to the power line VL through a contact hole of the second planarization layer 116 and a through hole of the first planarization layer 115. Therefore, the common electrode CE may be electrically connected to the first electrodes 134 of the plurality of light emitting diodes LED.

The common electrode CE is formed of a transparent conductive material to transmit light emitted from the plurality of light emitting diodes LED. For example, the common electrode CE may be formed of a transparent conductive material, such as indium tin oxide (ITO) or indium zinc oxide (IZO), but is not limited thereto.

The black bank BB is disposed on the common electrode CE. The black bank BB may be disposed to be spaced apart from the light emitting diode LED with a predetermined interval.

The black bank BB may be formed of an opaque material to reduce color mixture between the plurality of sub pixels SP and for example, may be formed of black resin, but is not limited thereto.

The third planarization layer 117 is disposed on the common electrode CE and the black bank BB. The third planarization layer 117 may planarize an upper portion of the black bank BB while being filled in a space between the black banks BB. The third planarization layer 117 may be configured by a single layer or a double layer, and for example, may be formed of photo resist or an acrylic-based organic material, but is not limited thereto.

The protection layer 118 is disposed on the third planarization layer 117 and the black bank BB. The protection layer 118 is a layer for protecting components below the protection layer 118, and may be configured by a single layer or a double layer of translucent epoxy, silicon oxide (SiOx) or silicon nitride (SiNx), but is not limited thereto.

The optical film MF may be disposed on the protection layer 118. The optical film MF may be a functional film which implements a higher quality of images while protecting the display device 100. For example, the optical film MF may include an anti-scattering film, an anti-glare film, an anti-reflecting film, a low-reflecting film, an Oled transmittance controllable film, or a polarizer, but is not limited thereto.

The exemplary embodiments of the present disclosure can also be described as follows:
In one embodiment, an interposer that transfers light emitting diodes onto a target substrate comprises: a base portion; and a plurality of protrusions on an upper surface of the base portion and spaced apart from each other on the upper surface of the base portion, each of the plurality of protrusions including a side wall extending in a direction away from the upper surface of the base portion, wherein the side wall defines an accommodation unit that is configured to contain a light emitting diode.

In one embodiment, the interposer further comprises: a plurality of insulating members, each of the plurality of insulating members disposed in a corresponding accommodation unit in one of the plurality of protrusions, wherein a coefficient of thermal expansion of the base portion and a coefficient of thermal expansion of the plurality of protrusions are smaller than a coefficient of thermal expansion of the plurality of insulating members.

In one embodiment, the plurality of insulating members include scattering particles, a photo conversion material, or a fluorescent material.

In one embodiment, the interposer further comprises: a coating layer covering the side wall in each of the plurality of protrusions, the coating layer including one or more of indium tin oxide, Teflon, or fluorine materials, wherein the base portion and the plurality of protrusions include glass or quartz and the plurality of insulating members include liquid silicon or acrylic material.

In one embodiment, the interposer further comprises: a bridge on the base portion, the bridge connecting lower portions of the plurality of protrusions.

In one embodiment, each of the plurality of protrusions further includes a bottom surface facing the base portion and surrounded by the side wall, and the bottom surface includes a flat surface.

In one embodiment, an inner surface of the side wall that is connected to the bottom surface forms an obtuse angle with the bottom surface.

In one embodiment, an inner surface of the side wall connected to the bottom surface forms an acute angle with the bottom surface.

In one embodiment, each of the plurality of protrusions further includes a bottom surface facing the base portion and surrounded by the side wall, and the bottom surface includes a plurality of patterns.

In one embodiment, an inner surface of the side wall is curved.

In one embodiment, the base portion includes a plurality of concave patterns in the upper surface of the base portion and the plurality of concave patterns overlap a plurality of accommodation units, wherein each of the plurality of concave patterns is connected to an inner surface of the side wall of a corresponding one of the plurality of protrusions.

In one embodiment, a method of manufacturing a display device, comprises: placing a temporary substrate above an interposer that includes a plurality of insulating members, wherein a plurality of light emitting diodes including a first electrode and a second electrode are disposed on the temporary substrate; transferring the plurality of light emitting diodes that are on the temporary substrate to the plurality of insulating members of the interposer, wherein a side surface and one surface of the first electrode of each of the plurality of light emitting diodes is surrounded by a corresponding insulating member from the plurality of insulating members after the plurality of light emitting diodes are transferred to the plurality of insulating members; and transferring the plurality of light emitting diodes that are on the plurality of insulating members and the plurality of insulating members to a target substrate by attaching the interposer to the target substrate.

In one embodiment, the method of manufacturing the display device further comprises: after the plurality of light emitting diodes and the plurality of insulating members are transferred to the target substrate: exposing the one surface of the first electrode of each of the plurality of light emitting diodes by removing a part of the corresponding insulating member that surrounds the light emitting diode; and forming a connection electrode on the plurality of light emitting diodes, the connection electrode electrically connecting the target substrate and the first electrode of each of the plurality of light emitting diodes.

In one embodiment, in transferring the plurality of light emitting diodes and the plurality of insulating members, one surface of the second electrode of each of the plurality of light emitting diodes is exposed by the corresponding insulating member, and transferring the plurality of light emitting diodes and the plurality of insulating members to the target substrate includes electrically connecting the one surface of the second electrode of each of the plurality of light emitting diodes to the target substrate.

In one embodiment, the method of manufacturing the display device further comprises: after the plurality of light emitting diodes and the plurality of insulating members are transfered to the target substrate, forming a plurality of reflection layers that cover side surfaces of the plurality of insulating members on the target substrate.

In one embodiment, forming the plurality of reflection layers includes: forming a metal layer that covers top surfaces and side surfaces of the plurality of insulating members; and exposing the top surfaces and a portion of the side surfaces that are connected to the top surfaces of the plurality of insulating members by removing a portion of the metal layer that covers the top surfaces and the portion of the side surfaces of the plurality of insulating members.

In one embodiment, the method of manufacturing the display device further comprises: after the top surfaces and the portion of the side surfaces of the plurality of insulating members are exposed: exposing the one surface of the first electrode of each of the plurality of light emitting diodes by removing a part of the plurality of insulating members; and forming a connection electrode that electrically connects the target substrate and the first electrode of each of the plurality of light emitting diodes.

In one embodiment, the interposer and the temporary substrate are not in contact with each other while the plurality of light emitting diodes are transferred to the plurality of insulating members.

In one embodiment, the method of manufacturing the display device further comprises: after the plurality of light emitting diodes and the plurality of insulating members are transfered to the target substrate, thermal curing or ultra violet light curing the plurality of insulating members that are transferred to the target substrate.

In one embodiment, the method of manufacturing the display device further comprises: prior to placing the temporary substrate, filling each of a plurality of accommodation units of the interposer with a corresponding insulating member from the plurality of insulating members.

In one embodiment, a display device comprises: a substrate; a thin film transistor on the substrate; a micro light emitting diode that is electrically connected to the thin film transistor, the micro light emitting diode including a first electrode; an insulating member in contact with and surrounding side surfaces and a portion of an upper surface of the micro light emitting diode such that at least a portion of the first electrode is exposed, the insulating member diffusing light emitted by the micro light emitting diode; a planarization layer surrounding a side surface of the insulating member; a common electrode on the planarization layer, the common electrode connected to the first electrode that is exposed by the insulating member; and a voltage line on the substrate, the voltage line connected to the common electrode.

In one embodiment, the micro light emitting diode includes a second electrode, and the display device further comprising: a reflective electrode that is connected to the thin film transistor; and a bonding layer that is disposed between the reflective electrode and the second electrode of the micro light emitting diode, the bonding layer connecting the reflective electrode to the second electrode of the micro light emitting diode.

In one embodiment, the insulating member is in direct contact with the bonding layer.

In one embodiment, the display device further comprises: a plurality of reflective side walls that surround a first portion of the side surface of the insulating member, the plurality of reflective side walls disposed on the reflective electrode and ends of the bonding layer.

In one embodiment, the planarization layer is in direct contact with a second portion of the side surface of the insulating member that is not surrounded by the plurality of reflective side walls.

In one embodiment, the insulating member comprises one of scattering particles, a photo conversion material, or a fluorescent material.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. An interposer that transfers light emitting diodes onto a target substrate, the interposer comprising:
a base portion; and
a plurality of protrusions on an upper surface of the base portion and spaced apart from each other on the upper surface of the base portion, each of the plurality of protrusions including a side wall extending in a direction away from the upper surface of the base portion,
wherein the side wall defines an accommodation unit that is configured to contain a light emitting diode.

2. The interposer according to claim 1, further comprising:
a plurality of insulating members, each of the plurality of insulating members disposed in a corresponding accommodation unit in one of the plurality of protrusions,
wherein a coefficient of thermal expansion of the base portion and a coefficient of thermal expansion of the plurality of protrusions are smaller than a coefficient of thermal expansion of the plurality of insulating members.

3. The interposer according to claim 2, wherein the plurality of insulating members include scattering particles, a photo conversion material, or a fluorescent material.

4. The interposer according to claim 2, further comprising:
a coating layer covering the side wall in each of the plurality of protrusions, the coating layer including one or more of indium tin oxide, Teflon, or fluorine materials,
wherein the base portion and the plurality of protrusions include glass or quartz and the plurality of insulating members include liquid silicon or acrylic material.

5. The interposer according to claim 1, further comprising:
a bridge on the base portion, the bridge connecting lower portions of the plurality of protrusions.

6. The interposer according to claim 1, wherein each of the plurality of protrusions further includes a bottom surface facing the base portion and surrounded by the side wall, and the bottom surface includes a flat surface.

7. The interposer according to claim 6, wherein an inner surface of the side wall that is connected to the bottom surface forms an obtuse angle with the bottom surface.

8. The interposer according to claim 6, wherein an inner surface of the side wall connected to the bottom surface forms an acute angle with the bottom surface.

9. The interposer according to claim 1, wherein each of the plurality of protrusions further includes a bottom surface facing the base portion and surrounded by the side wall, and the bottom surface includes a plurality of patterns.

10. The interposer according to claim 1, wherein an inner surface of the side wall is curved.

11. The interposer according to claim 1, wherein the base portion includes a plurality of concave patterns in the upper surface of the base portion and the plurality of concave patterns overlap a plurality of accommodation units,
wherein each of the plurality of concave patterns is connected to an inner surface of the side wall of a corresponding one of the plurality of protrusions.

12. A method of manufacturing a display device, comprising:
placing a temporary substrate above an interposer that includes a plurality of insulating members, wherein a plurality of light emitting diodes including a first electrode and a second electrode are disposed on the temporary substrate;
transferring the plurality of light emitting diodes that are on the temporary substrate to the plurality of insulating members of the interposer, wherein a side surface and one surface of the first electrode of each of the plurality of light emitting diodes is surrounded by a corresponding insulating member from the plurality of insulating members after the plurality of light emitting diodes are transferred to the plurality of insulating members; and
transferring the plurality of light emitting diodes that are on the plurality of insulating members and the plurality of insulating members to a target substrate by attaching the interposer to the target substrate.

13. The method of manufacturing the display device according to claim 12, further comprising:
after the plurality of light emitting diodes and the plurality of insulating members are transferred to the target substrate:
exposing the one surface of the first electrode of each of the plurality of light emitting diodes by removing a part of the corresponding insulating member that surrounds the light emitting diode; and
forming a connection electrode on the plurality of light emitting diodes, the connection electrode electrically connecting the target substrate and the first electrode of each of the plurality of light emitting diodes.

14. The method of manufacturing the display device according to claim 13, wherein in transferring the plurality of light emitting diodes and the plurality of insulating members, one surface of the second electrode of each of the plurality of light emitting diodes is exposed by the corresponding insulating member, and transferring the plurality of light emitting diodes and the plurality of insulating members to the target substrate includes electrically connecting the one surface of the second electrode of each of the plurality of light emitting diodes to the target substrate.

15. The method of manufacturing the display device according to claim 12, further comprising:
after the plurality of light emitting diodes and the plurality of insulating members are transfered to the target substrate, forming a plurality of reflection layers that cover side surfaces of the plurality of insulating members on the target substrate.

16. The method of manufacturing the display device according to claim 15, wherein forming the plurality of reflection layers includes:
forming a metal layer that covers top surfaces and side surfaces of the plurality of insulating members; and
exposing the top surfaces and a portion of the side surfaces that are connected to the top surfaces of the plurality of insulating members by removing a portion of the metal layer that covers the top surfaces and the portion of the side surfaces of the plurality of insulating members.

17. The method of manufacturing the display device according to claim 16, further comprising:
after the top surfaces and the portion of the side surfaces of the plurality of insulating members are exposed:
exposing the one surface of the first electrode of each of the plurality of light emitting diodes by removing a part of the plurality of insulating members; and
forming a connection electrode that electrically connects the target substrate and the first electrode of each of the plurality of light emitting diodes.

18. The method of manufacturing the display device according to claim 12, wherein the interposer and the temporary substrate are not in contact with each other while the plurality of light emitting diodes are transferred to the plurality of insulating members.

19. The method of manufacturing the display device according to claim 12, further comprising:
after the plurality of light emitting diodes and the plurality of insulating members are transfered to the target substrate, thermal curing or ultra violet light curing the plurality of insulating members that are transferred to the target substrate.

20. The method of manufacturing the display device according to claim 12, further comprising:
prior to placing the temporary substrate, filling each of a plurality of accommodation units of the interposer with a corresponding insulating member from the plurality of insulating members.

21. A display device comprising:
a substrate;
a thin film transistor on the substrate;
a micro light emitting diode that is electrically connected to the thin film transistor, the micro light emitting diode including a first electrode;
an insulating member in contact with and surrounding side surfaces and a portion of an upper surface of the micro light emitting diode such that at least a portion of the first electrode is exposed, the insulating member diffusing light emitted by the micro light emitting diode;
a planarization layer surrounding a side surface of the insulating member;
a common electrode on the planarization layer, the common electrode connected to the first electrode that is exposed by the insulating member; and
a voltage line on the substrate, the voltage line connected to the common electrode.

22. The display device of claim 21, wherein the micro light emitting diode includes a second electrode, and the display device further comprising:
a reflective electrode that is connected to the thin film transistor; and
a bonding layer that is disposed between the reflective electrode and the second electrode of the micro light emitting diode, the bonding layer connecting the reflective electrode to the second electrode of the micro light emitting diode.

23. The display device of claim 22, wherein the insulating member is in direct contact with the bonding layer.

24. The display device of claim 22, further comprising:
a plurality of reflective side walls that surround a first portion of the side surface of the insulating member, the plurality of reflective side walls disposed on the reflective electrode and ends of the bonding layer.

25. The display device of claim 24, wherein the planarization layer is in direct contact with a second portion of the side surface of the insulating member that is not surrounded by the plurality of reflective side walls.

26. The display device of claim 21, wherein the insulating member comprises one of scattering particles, a photo conversion material, or a fluorescent material.
